(19) United States
(12) Patent Application Publication
(10) Pub. No.: US 2014/0252529 A1
(43) Pub. Date: Sep. 11, 2014

(54) Pb-salt Mid-infrared Detectors and Method for Making Same

(71) Applicant: The Board of Regents of the University of Oklahoma, Norman, OK (US)

(72) Inventors: Zhisheng Shi, Norman, OK (US); Jijun Qiu, Norman, OK (US); Binbin Weng, Norman, OK (US); Zijian Yuan, Norman, OK (US)

(21) Appl. No.: 14/193,681

(22) Filed: Feb. 28, 2014

Related U.S. Application Data
(60) Provisional application No. 61/887,009, filed on Oct. 4, 2013.
(60) Provisional application No. 61/773,664, filed on Mar. 6, 2013.

(51) Int. Cl. H01L 31/032; H01L 31/18; H01L 31/0272

(52) U.S. Cl. CPC H01L 31/0324; H01L 31/0272; H01L 31/18
USPC 257/441; 252/519.4; 438/95

(57) ABSTRACT

The disclosure describes methods for preparing lead salt materials which are sensitive to the mid-infrared spectrum which can be used to manufacture high-uniformity, high-detectivity, polycrystalline lead salt photoconductive and photovoltaic photodetectors.

### RELATED APPLICATIONS

The present patent application incorporates by reference the entire provisional patent application identified by U.S. Ser. No. 61/773,664, filed on Mar. 6, 2013 and the entire provisional patent application identified by U.S. Ser. No. 61/887,009, filed on Oct. 4, 2013, and claims priority thereto under 35 U.S.C. 119(e).

### STATEMENT REGARDING FEDERALLY SPONSORED RESEARCH OR DEVELOPMENT

This invention was made with government support under Contract Number FA9550-12-1-0451 awarded by the Air Force Office of Scientific Research (AFOSR) and W911NF-07-1-0587 awarded by the Army Research Office (ARO). The government has certain rights in the invention.

### BACKGROUND

Photodetectors are devices which receive optical energy (light or other electromagnetic radiation) and convert it into electrical energy (e.g., a current). Uncooled photoconductive detectors (i.e., detectors which do not require cooling during operation) are often preferred over other more sensitive detectors which do have a cooling requirement, because the former can be run at ambient temperatures.

After many years' development since 1930's, high-temperature, low-cost PbS and PbSe polycrystalline photoconductive detectors remain the choice for many applications in the 1-3 μm and 3-5 μm spectral range. Lead-salt photoconductive detectors are made first by depositing a lead-salt layer (e.g., PbSe, PbS, or PbTe) on a substrate such as silicon. Regardless of deposition techniques, as-grown Pb-salt poly-crystalline films are “dead” or non-sensitive until made responsive by thermal treatment under certain atmospheres to become sensitive to infrared radiation, in a process known as sensitization.

Chemically-deposited lead salt films such as lead selenide and lead sulfide films possess highly desirable properties for use in detecting mid-infrared radiation. Therefore, lead selenide and lead sulfide photoconductive detectors have become extremely important, particularly in the field of military defense against jet or rocket-powered aircraft and missiles. To obtain maximum information and enhance background discrimination, it is desirable to form high detectivity lead salt films in the form of complex or intricate arrays patterns. Unfortunately, it has been difficult to produce lead salt films by standard chemical solution methods which meet the desired sensitivity at uncooled temperatures (i.e., temperatures which do not require cooling by an external cooling device such as a cryocooler, for example). Therefore, how to improve the detectivity and further decrease the cost of uncooled mid-infrared lead salt detectors produced by the chemical solution method has been an area of research.

### BRIEF DESCRIPTION OF THE DRAWINGS

Several embodiments of the presently disclosed inventive concepts are hereby illustrated in the appended drawings. It is to be noted however, that the appended drawings only illustrate several typical embodiments and are therefore not intended to be considered limiting of the scope of the presently disclosed inventive concepts. Further, in the appended drawings, like or identical reference numerals or letters may be used to identify common or similar elements and not all such elements may be so numbered. The figures are not necessarily to scale and certain features and certain views of the figures may be shown as exaggerated in scale or in schematic in the interest of clarity and conciseness.

FIG. 1 shows SEM images of PbSe polycrystalline films (top view and side view (inset)): (a) Sample I is as-grown, (b) Sample II sensitized and annealed at 380° C. in pure nitrogen for 30 min, (c) Sample III sensitized and annealed at 380° C. in nitrogen for 20 min followed by oxygen for 10 min, (d) Sample V sensitized and annealed at 380° C. in nitrogen for 25 min followed by iodine for 5 min, (e) Sample IV sensitized and annealed at 380° C. in pure oxygen for 30 min, (f) Sample VI sensitized and annealed at 380° C. in oxygen for 25 min followed by iodine for 5 min.

FIG. 2 shows photoluminescence (PL) emission spectra of PbSe polycrystalline films (a) Sample I is as-grown, (b) Sample II sensitized and annealed at 380° C. in pure nitrogen for 30 min, (c) Sample III sensitized and annealed at 380° C. in nitrogen for 20 min followed by oxygen for 10 min, (d) Sample IV sensitized and annealed at 380° C. in pure oxygen for 30 min, (e) Sample V sensitized and annealed at 380° C. in nitrogen for 25 min followed by iodine for 5 min, (f) Sample VI sensitized and annealed at 380° C. in oxygen for 25 min followed by iodine for 5 min, (g) Sample VII sensitized and annealed at 380° C. in mixed oxygen and iodine for 5 min.

FIG. 3 shows X-ray diffraction curves of (a) as-grown PbSe films grown on Si substrate, and (b) sensitized PbSe films annealed at 380° C. in 25-min oxygen followed by 5-min iodine atmosphere.

FIG. 4 shows the relationship of peak intensity of PL emission spectra to microcrystal size of sensitized PbSe annealed at 380° C. in pure oxygen for 30 min.

FIG. 5 shows a cross-sectional view of one embodiment of a detector constructed in accordance with the presently disclosed inventive concepts.

FIG. 6 shows a cross-sectional view of another embodiment of a detector constructed in accordance with the presently disclosed inventive concepts.

FIG. 7 shows a cross-sectional view of another embodiment of a photodetector constructed in accordance with the presently disclosed inventive concepts.

### DETAILED DESCRIPTION

The presently disclosed inventive concepts provide a reliable method for improving the detectivity of chemically deposited lead salt films and for decreasing the cost of lead salt film photoconductive and photovoltaic detectors.

Before explaining at least one embodiment of the presently described inventive concepts in detail by way of exemplary drawings, experimentation, results, and laboratory procedures, it is to be understood that the inventive concepts are not limited in its application to the details of construction and the arrangement of the components and steps set forth in the following description or illustrated in the drawings, experimentation and/or results. The inventive concepts are capable of other embodiments or of being practiced or carried out in various ways. As such, the language used herein is intended to be given the broadest possible scope and meaning; and the embodiments are meant to be exemplary, not exhaustive. Also, it is to be understood that the phraseology and terminology employed herein is for the purpose of description and should not be regarded as limiting.

Unless otherwise defined herein, scientific and technical terms used in connection with the presently disclosed inventive concepts shall have the meanings that are commonly understood by those of ordinary skill in the art. Further, unless otherwise required by context, singular terms shall include pluralities and plural terms shall include the singular. Generally, nomenclatures utilized herein are those well known and commonly used in the art. The nomenclatures utilized herein are those well known and commonly used in the art.

All patents, published patent applications and non-patent publications mentioned in the specification are indicative of the level of skill of those skilled in the art to which this presently disclosed inventive concepts pertain. All patents, published patent applications and non-patent publications referenced in any portion of this application are herein expressly incorporated by reference in their entirety to the same extent as if each individual patent or publication was specifically and individually indicated to be incorporated by reference.

All of the compositions and/or methods disclosed herein can be made and executed without undue experimentation in light of the present disclosure. While the compositions and methods of this disclosure have been described in terms of particular embodiments, it will be apparent to those of skill in the art that variations may be applied to the compositions and/or methods and in the steps or in the sequence of steps of the methods described herein without departing from the concept, spirit and scope of the disclosure. All such similar substitutes and modifications apparent to those skilled in the art are deemed to be within the spirit, scope and concept of the inventive concepts as defined by the appended claims.

As utilized in accordance with the present disclosure, the following terms, unless otherwise indicated, shall be understood to have the following meanings: The use of the word “a” or “an” when used in conjunction with the term “comprising” in the claims and/or the specification may mean “one,” but it is also consistent with the meaning of “one or more,” “at least one,” and “one or more than one.” The use of the term “or” in the claims is used to mean “and/or” unless explicitly indicated to refer to alternatives only or the alternatives are mutually exclusive, although the disclosure supports a definition that refers to only alternatives and “and/or.” The use of the term “at least one” will be understood to include one as well as any quantity more than one, including but not limited to, 2, 3, 4, 5, 10, 15, 20, 30, 40, 50, 100, etc. The term “at least one” may extend up to 100 or 1000 or more, depending on the term to which it is attached; in addition, the quantities of 100/1000 are not to be considered limiting, as higher limits may also produce satisfactory results. In addition, the use of the term “at least one of X, Y and Z” will be understood to include X alone, Y alone, and Z alone, as well as any combination of X, Y and Z. Throughout this application, the term “about” is used to indicate that a value includes the inherent variation of error for the composition or item of manufacture, the method used to make the composition or item of manufacture, or the variation that exists among the composition or item of manufacture or the methods used to make the composition or item of manufacture. For example, but not by way of limitation, when the term “about” is utilized, the designated value may vary by plus or minus twelve percent, or by plus or minus eleven percent, or by plus or minus ten percent, or by plus or minus nine percent, or by plus or minus eight percent, or by plus or minus seven percent, or by plus or minus six percent, or by plus or minus five percent, or by plus or minus four percent, or by plus or minus three percent, or by plus or minus two percent, or by plus or minus one percent, or by plus or minus one-half percent.

As used herein, the term “substantially” means that the subsequently described event, circumstance, or item completely occurs or that the subsequently described event, circumstance or item occurs to a great extent or degree. In some embodiments for example, the term “substantially” means that the subsequently described event, circumstance, or item occurs at least 75% of the time, or at least 80% of the time, or at least 85% of the time, or at least 90% of the time, or at least 95% of the time, or at least 98% of the time. The term “substantially” may also be used in reference to purity, for example the term “substantially pure” refers to a composition or mixture which contains a compound, wherein the predominant compound in the composition or mixture comprises at least 95% of the composition or mixture. The term “pure” may include compounds or compositions which are “substantially pure.” A composition having “low purity” general has less than 50% of the predominant gas. For example an oxygen atmosphere with low purity generally comprises less than 50% oxygen.

As used in this specification and claims, the words “comprising” (and any form of comprising, such as “comprise” and “comprises”), “having” (and any form of having, such as “have” and “has”), “including” (and any form of including, such as “includes” and “include”) or “containing” (and any form of containing, such as “contains” and “contain”) are inclusive or open-ended and do not exclude additional, unrecited elements or method steps.

The term “or combinations thereof” as used herein refers to all permutations and combinations of the listed items preceding the term. For example, “A, B, C, or combinations thereof” is intended to include at least one of: A, B, C, AB, AC, BC, or ABC, and if order is important in a particular context, also BA, CA, CB, CBA, BCA, ACB, BAC, or CAB. Continuing with this example, expressly included are combinations that contain repeats of one or more item or term, such as BB, AAA, AAB, BBC, AAABCCCC, CBBAAA, CABABB, and so forth. The skilled artisan will understand that typically there is no limit on the number of items or terms in any combination, unless otherwise apparent from the context.

Further, in this detailed description and the appended claims, each numerical value (e.g., temperature or time) should be read once as modified by the term “about” (unless already expressly so modified), and then read again as not so modified unless otherwise indicated in context. Also, any range listed or described herein is intended to include, implicitly or explicitly, any number within the range, particularly all integers, including the end points, and is to be considered as having been so stated. For example, “a range from 1 to 10” is to be read as indicating each possible number, particularly integers, along the continuum between about 1 and about 10. Thus, even if specific data points within the range, or even no data points within the range, are explicitly identified or specifically referred to, it is to be understood that any data points within the range are to be considered to have been specified, and that the inventors possessed knowledge of the entire range and the points within the range.

The term “detectivity” as used herein refers to specific detectivity D* and is a measure of detector performance.

Turning now to the presently disclosed inventive concepts, the present disclosure relates to methods for preparing lead salt materials which are sensitive to mid-infrared spectrum. More particularly, but not by way of limitation, the present disclosure pertains to a low-cost chemical solution method for forming high-detectivity, uncooled polycrystalline lead salt photoconductive and photovoltaic photodetectors.

As explained above, photodetectors are devices which receive optical energy (light or other electromagnetic radiation) and convert it into electrical energy (e.g., a current). Non-cooled photoconductive detectors (i.e., those which do not require cooling during operation) are often desired over other more sensitive detectors which do have a cooling requirement, because the former can be run at ambient temperatures. Lead-salt photoconductive detectors are made first by depositing a lead-salt layer (such as, but not limited to, PbSe, PbS, PbTe and other lead salts described herein) on a substrate such as silicon. Also as noted above, “as-grown” Pb-salt polycrystalline films are “dead” or non-sensitive (i.e., substantially inactive) until made responsive by thermal treatment under certain atmospheres to become sensitive to infrared radiation, in a process known as sensitization.

Presently, it has been discovered that, although oxygen is a useful sensitizing improver, optimization of the photo-response (detectivity) of lead-salt photoconductive and photovoltaic detectors is dependent on exposure to iodine. Thus, the present disclosure in one embodiment is directed to a process for (1) making the lead-salt coated substrates, for example by using chemical bath deposition (CBD), and (2) sensitizing the lead-salt coated substrate using a high temperature sensitization step involving exposure of the lead-salt coated substrate to iodine. The iodine can be provided as I₂ vapor in an atmosphere which is substantially pure iodine, or can be provided in an atmosphere which is primarily iodine (50%), or can be provided in a “low purity” mixture with other gases, wherein the iodine comprises <50% of the composition. The iodine vapor can be provided in a pure form or as a mixture of gases including, for example but not necessarily limited to, one or more of oxygen, nitrogen, air, and the noble gases such as helium, argon, neon, krypton, and xenon. For example, the iodine vapor can be supplied as a component of an air mixture, an oxygen mixture, a nitrogen mixture, an argon mixture, a helium mixture, an air-argon mixture, an air-helium mixture, an air-oxygen mixture, an air-nitrogen mixture, an oxygen-argon mixture, a nitrogen-argon mixture, an oxygen-nitrogen mixture, an argon-helium mixture, an air-oxygen-nitrogen mixture, an air-argon-oxygen mixture, or an air-argon-nitrogen mixture. The above examples of iodine-gas mixtures are non-limiting examples of iodine-gas mixtures which can be used herein. In another embodiment, the iodine sensitization step can be preceded by exposure to at least one of oxygen and nitrogen, as explained further below.

Lead salts which can be used in the detectors of the presently disclosed inventive concepts include, but are not limited to: PbS, PbSe, PbTe, PbSnSe, PbSnTe, PbSrSe, PbSrTe, PbEuSe, PbEuTe, PbCdSe, PbCdTe, and any lead salt containing a combination of two, three, four, or more Group IV and Group VI elements. Substrates which may be used in the present disclosure include, but are not limited to, silicon, glass, silica, quartz, sapphire, CaF₂, SiO₂, and other substrates commonly used by persons having ordinary skill in the art to construct photodetectors. In one embodiment the substrate upon which the Pb-salt film is deposited can be constructed to comprise a plurality of spaced-apart wells in the upper surface thereof, such as described in U.S. Published Patent Application 2012/0326210, the entirety of which is expressly incorporated herein by reference.

The sensitized lead salt-coated substrates described herein are used to construct uncooled photoconductive and photovoltaic detectors which have high detectivities. In certain embodiments the detectors have detectivities of at least 2×10⁹ cm·Hz^{1/2}·W⁻¹ as measured at room temperature (298K), i.e., are uncooled. For example, the detectors may have detectivities within a range of 2×10⁹ cm·Hz^{1/2}·W⁻¹ to 2.8×10¹⁰ cm·Hz^{1/2}·W⁻¹ to 2×10¹¹ cm·Hz^{1/2}·W⁻¹ as measured at room temperature (298K), i.e., are uncooled. Alternatively, the detectors may have detectivities within a range of 2×10⁹ cm·Hz^{1/2}·W⁻¹ to 2.8×10¹⁰ cm·Hz^{1/2}·W⁻¹ to 1.5×10¹¹ cm·Hz^{1/2}·W⁻¹ as measured at room temperature (298K), i.e., are uncooled. Alternatively, the detectors may have detectivities within a range of 2×10⁹ cm·Hz^{1/2}·W⁻¹ to 2.8×10¹⁰ cm·Hz^{1/2}·W⁻¹ to 1.25×10¹¹ cm·Hz^{1/2}·W⁻¹ as measured at room temperature (298K), i.e., are uncooled. Alternatively, the detectors may have detectivities within a range of 2×10⁹ cm·Hz^{1/2}·W⁻¹ to 2.8×10¹⁰ cm·Hz^{1/2}·W⁻¹ to 1×10¹¹ cm·Hz^{1/2}·W⁻¹ as measured at room temperature (298K), i.e., are uncooled. Alternatively, the detectors may have detectivities within a range of 2×10⁹ cm·Hz^{1/2}·W⁻¹ to 2.8×10¹⁰ cm·Hz^{1/2}·W⁻¹ to 9×10¹⁰ cm·Hz^{1/2}·W⁻¹ as measured at room temperature (298K), i.e., are uncooled. Alternatively, the detectors may have detectivities within a range of 2×10⁹ cm·Hz^{1/2}·W⁻¹ to 2.8×10¹⁰ cm·Hz^{1/2}·W⁻¹ to 8×10¹⁰ cm·Hz^{1/2}·W⁻¹ as measured at room temperature (298K), i.e., are uncooled. Alternatively, the detectors may have detectivities within a range of 2×10⁹ cm·Hz^{1/2}·W⁻¹ to 2.8×10¹⁰ cm·Hz^{1/2}·W⁻¹ to 7×10¹⁰ cm·Hz^{1/2}·W⁻¹ as measured at room temperature (298K), i.e., are uncooled. Alternatively, the detectors may have detectivities within a range of 2×10⁹ cm·Hz^{1/2}·W⁻¹ to 2.8×10¹⁰ cm·Hz^{1/2}·W⁻¹ to 6×10¹⁰ cm·Hz^{1/2}·W⁻¹ as measured at room temperature (298K), i.e., are uncooled. Alternatively, the detectors may have detectivities within a range of 2×10⁹ cm·Hz^{1/2}·W⁻¹ to 2.8×10¹⁰ cm·Hz^{1/2}·W⁻¹ to 5×10¹⁰ cm·Hz^{1/2}·W⁻¹ as measured at room temperature (298K), i.e., are uncooled.

Uniformity (homogeneity) of chemically-deposited lead salt films on substrates used in detectors of the presently disclosed inventive concepts can be improved by enhancing the adhesion between the lead salt films with the substrates, which may be carried out by three routes. Firstly, the mismatch thermal expansion coefficient between the lead salt and substrate is lowered in one embodiment by substituting calcium fluoride for conventional glass, quartz and sapphire substrates, which increases the heat-stability of the lead salt in the later heat-sensitization process. Secondly, in the case of lead selenide, the growth rate of chemically deposited lead selenide is decreased by substituting selenosulfate for selenourea as selenium source, which makes it easy to precisely control the composition and morphology of lead selenide. Thirdly, ultrasonic assistance growth is introduced to the whole chemical deposition process, which is helpful for a uniform crystal size of lead salt.

Certain examples of the presently disclosed inventive concepts described below are non-limiting examples of embodiments of the process and detectors of the disclosure, as applied to a lead selenide detector, but which are also applicable to other Pb salt detectors. It is understood that the present disclosure is not limited in its application to the specific experimentation, results and laboratory procedures described herein. Rather, the examples are simply provided as several of various embodiments and are meant to be exemplary, not exhaustive.

Responsivity and PL measurements on polycrystalline samples grown by chemical bath deposition (CBD) and sensitized under various atmospheres were conducted. The results show that it is iodine, instead of oxygen, that plays the most critical role in the sensitization procedure of p-type Pb salt (e.g., PbSe) photoconductive or photovoltaic detectors. Oxygen, while still important, only serves as a very effective sensitization improver and when used alone does not result in the attainment of the high detectivities described herein.

Without wishing to be bound by theory, these results indicate that O₂ annealing only helps recrystallization, defect passivation and formation of an oxidation layer on the boundaries. In one embodiment, the presently described novel process is the first to use a step of exposure to pure oxygen in an annealing step to improve the crystal quality followed by exposure to I₂ to sensitize the material. Without wishing to be bound by theory, it is believed that the sensitization is caused by I₂ introducing p-n junctions on the surfaces or the crystallites. Temperature and time for I₂ annealing may vary depending on the crystallite size and the surface conditions after the O₂ annealing step.

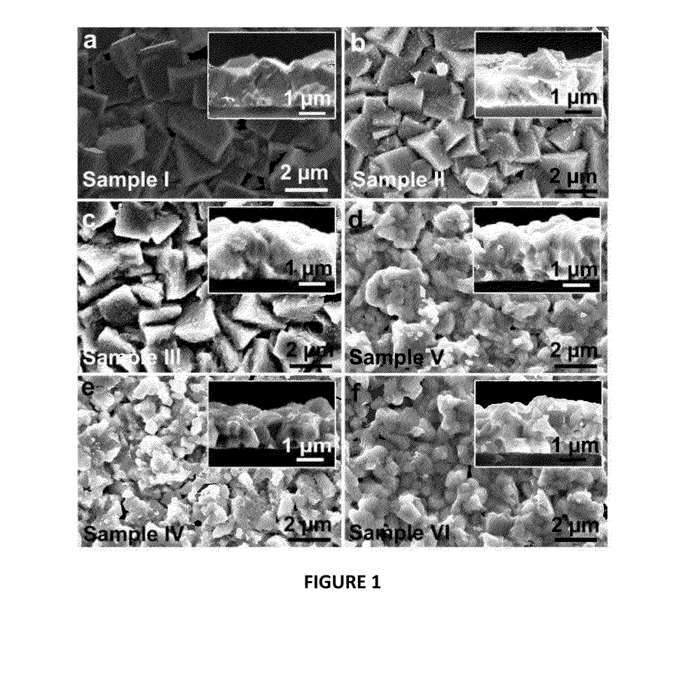

In one example, PbSe polycrystalline films were fabricated on glass and (111) Si substrates by using CBD. In brief, the aqueous precursor was prepared via dissolving sodium hydroxide, lead acetate and selenosulfate with a concentration ratio of 12:1:1. The cleaned glass substrates were transferred into the aqueous precursor and maintained at 70° C. for 1.5 hours. Films treated by various sensitization conditions are shown in FIG. 1. The as-grown PbSe film (Sample I) shows a loose compact structure with microcrystal sizes and thickness ranging typically between 0.7-1.2 μm and 1.1-1.2 μm, as shown in FIG. 1a. To better understand the sensitization process, as-grown PbSe films were then annealed in well-designed atmospheres at 380° C. for a constant total annealing time, including: 30-minutes pure nitrogen (Sample II), 20-minutes nitrogen followed by 10-minutes oxygen (Sample III), 30-minutes pure oxygen (Sample IV), 25-minutes nitrogen followed by 5-minute iodine (Sample V), 25-minutes oxygen followed by 5-minutes iodine (Sample VI), mixed oxygen and iodine for 5 minutes (Sample VII), and 15-minutes nitrogen followed 10-minutes oxygen and 5-minutes iodine (Sample VIII), respectively. The flow was kept at a constant rate of 0.05 psi. Both hot probe and Hall measurement show that the all as-grown and after-annealing samples are p-type. 200 nm thick gold thin films were then deposited by thermal evaporation over two sides of the PbSe detectors with a 2×2 mm² active area. The detectivity measurements were performed at room temperature (298 K) using a lock-in amplifier and a collimated black-body, with irradiation of 6×10⁻⁵ W·cm⁻² at 500 K, chopped at 750 Hz. The devices were biased at 100 V, with a load resistor matched to the sensor resistance.

Table 1 summarizes the experimental results on the sensitization of uncooled PbSe infrared photoconductive detectors. Firstly, a high peak detectivity up to 1.0×10¹⁰ cm·Hz^{1/2}·W⁻¹ was observed by annealing p-type PbSe microcrystalline films obtained via CBD in nitrogen and iodine atmosphere without oxygen. Secondly, the use of pure oxygen followed by exposure to iodine (Sample VI) could further enhance the PbSe detectivity to at least about two times larger (2.8×10¹⁰ cm·Hz^{1/2}·W⁻¹) than those sensitized in an iodine-nitrogen atmosphere. This shows that oxygen can significantly improve the PbSe sensitivity. Thirdly, no photo-response was obtained from PbSe samples (Samples I-IV) annealed in atmospheres that did not contain iodine, including those subjected to pure oxygen, indicating that it is exposure to iodine rather than oxygen that is the optimal step in activating (sensitizing) the PbSe photo-response. In addition to the annealing atmosphere, sufficient annealing time at high temperature (e.g., a temperature in a range of 300° C. to 450° C.) is also useful for high photo-response.

### Table 1.

TABLE 1
Characterizations of uncooled PbSe detectors and the annealing
conditions to which they were exposed during formation

| | | Resis- | Respon- | D* |
|---|---|---|---|---|
| Sample | Annealed | tance | sibility | (λₚ, 750, 1) |
| # | Atmosphere | (MΩ) | at λₚ (V/W) | (cmHZ^{1/2} W⁻¹) |
| Sample | As-Grown | 0.02 | / | / |
| I | | | | |
| Sample | Nitrogen | 0.05 | / | / |
| II | | | | |
| Sample | Nitrogen/Oxygen | 0.06 | / | / |
| III | | | | |
| Sample | Oxygen | 0.1 | / | / |
| IV | | | | |
| Sample | Nitrogen/Iodine | 2.0 | 1.8E+04 | 1.0E+10 |
| V | | | | |
| Sample | Oxygen/Iodine | 4.0 | 3.1E+04 | 2.8E+10 |
| VI | | | | |
| Sample | Oxygen + Iodine * | 2.0 | 5.9E+03 | 1.2E+09 |
| VII | | | | |
| Sample | Nitrogen/ | 2.5 | 2.9E+04 | 2.5E+10 |
| VIII | Oxygen/Iodine | | | |

(“/” represents “followed-by”)

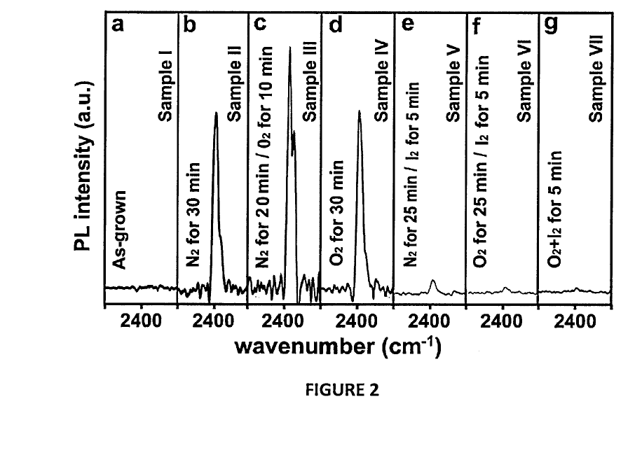

To further analyze these results, photoluminescence (PL) studies on Samples I-VII listed in Table 1 were performed. The room temperature PL emission spectra shown in FIG. 2 were characterized by a Fourier Transform Infrared (FTIR) spectrometer in Step-Scan mode with a 1.064 μm Q-switched Nd:YAG pumping laser (τ pulse=5 ns, 10 Hz). No PL emission is observed in as-grown p-type PbSe film (FIG. 2a, Sample I). After the annealing process, however, PL peaks emerge in all annealed PbSe films, as shown in FIGS. 2b to 2g, though there are significant differences in their PL intensities. PL intensity of pure-nitrogen annealed PbSe film (FIG. 2b, Sample II) is comparable with that with pure oxygen (FIG. 2d, Sample IV). Oxygen annealing after nitrogen annealing significantly increases the PL intensity (FIG. 2c, Sample III). On the contrary, PL intensity dramatically decreases after introducing iodine, and exposure to iodine following exposure to oxygen causes a more rapid PL degradation than results when nitrogen, then iodine are exposed to the PbSe film, as shown in FIG. 2e (Sample V) and 2f (Sample VI), respectively.

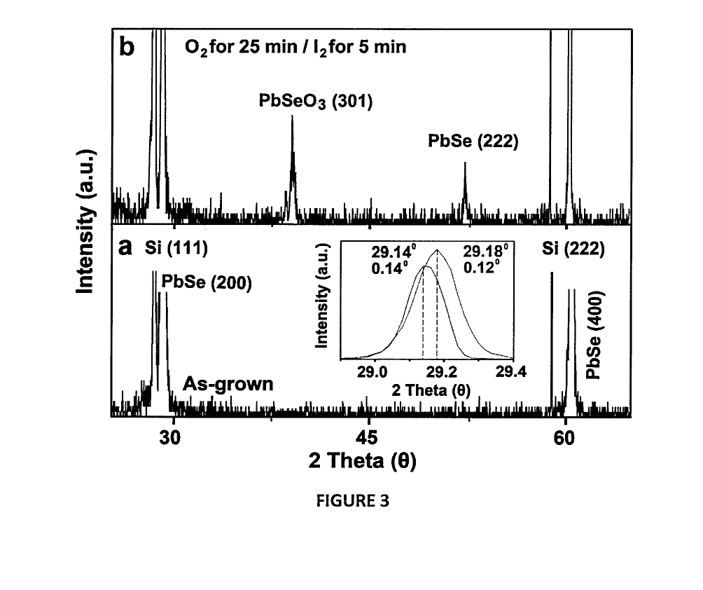

Without wishing to be bound by theory, it is suggested that there are at least four factors that dominate the PL intensities, including: material gain, loss mechanisms including surface/interface recombination, extraction efficiency, and the effective pumping due to the diffuse pumping light. It is well known that compared with high-temperature physical methods such as molecular beam epitaxy (MBE), a disadvantage of CBD technique is lower crystal quality due to the numbers of intrinsic defects, such as lead vacancies (V″_{b}) and selenium interstitials (S_{ï}) (as-grown PbSe is p-type in the present case). These defects can be attributed to the low growth temperature and the impurity containments from the aqueous precursors. It has been reported that oxygen and sodium ion may be incorporated into PbSe films during the deposition process to form (Xₓ Pb₁₋ₓ)(Y_{y}Se_{1-y}), where X stands for metal impurity and Y stands for non-metal impurity. However, a portion of the defects could be eliminated by a recrystallization process during high temperature annealing, which improves the crystal quality. Therefore, the occurrence of PL peaks after annealing is a good indication of improved crystal quality. This is confirmed by the higher X-ray diffraction (XRD) peak intensity (Cu, Kα) and narrower full width at half maximum (FWHM) of PbSe (200) peak annealed in oxygen followed by exposure to an iodine-containing atmosphere, as shown in FIG. 3.

Factors which may affect the quality of recrystallization include annealing temperature, time and atmosphere. Since annealing temperature and total annealing time in the experiments were kept the same, the significant differences in PL peak intensities after annealing must be caused by the different annealing atmospheres to which the crystals were exposed. Since no remarkable roughness change was observed from the SEM images of all treated PbSe films, as shown in FIG. 1b to 1f, differences in extraction efficiency and effective pumping can be ignored. Owing to its highly reactive nature, oxygen could firstly react with the V″_{Pb} and Se_{ï} defects located in surface of PbSe microcrystals via diffusion in rich-oxygen atmosphere. However, long-time oxygen annealing could result in a serious deviation from stoichiometry of PbSe microcrystals due to overreaction with Pb²⁺, and Se²⁻. It will also form PbSe₁₋ₓOₓ, even insulating PbO layers on the surfaces and boundaries of PbSe microcrystals. This crystal-phase transformation is generally observed in rich-oxygen sensitized PbSe process, regardless of synthetic methods. In the present case, PbSeO₃ was detected in XRD pattern of the sensitized PbSe as shown in FIG. 3b. Compared with pure nitrogen sensitized PbSe films (Sample II), a more distinct boundary coalescent between adjacent PbSe microcrystal showing in FIG. 1f (Sample IV) and the increase in resistance from 0.05 to 0.1MÙ clearly verify the oxidation process. Both stoichiometric deviation and over-oxidation lead to lattice defects, and thus degrade crystal quality. Therefore, the highest PL intensity on sample III (annealed with O₂ after N₂) annealing was attributed to a result of good combination of recrystallization and defect passivation.

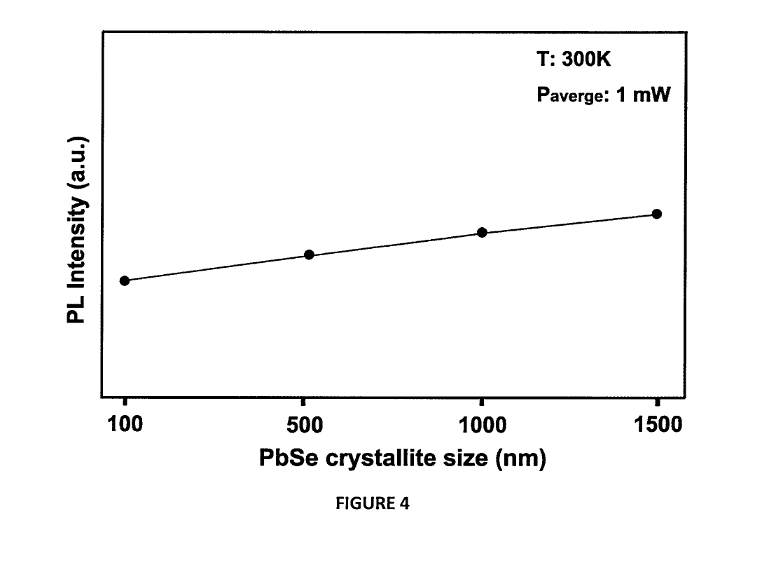

However, no photo-response was observed in any sample of high PL intensity. Considering that photosensitivity is sensitive to microcrystal size, four 1.2 μm thick PbSe films with different microcrystal sizes ranging from 0.1 to 1.5 μm were fabricated. After annealing in pure oxygen atmosphere for 30 min, all samples showed similarly much enhanced PL intensity as shown in FIG. 4. However, no photo-response was observed on any of these four PbSe films, which confirms that oxygen alone does not sensitize p-type PbSe.

After introducing iodine to both the nitrogen-annealed (Sample V) and oxygen-annealed (Sample VI) PbSe films for 5 min, high photo responses were observed and Sample VI (annealed with oxygen) showed higher detectivity, as shown in Table 1. Therefore, it is demonstrated herein that iodine, not oxygen, plays a necessary role in photo-response of Pb-salt microcrystals (e.g., at ambient temperature). Without wishing to be bound by theory, the comparison and analysis of PL and SEM images before and after introducing iodine provides some useful insight into how iodine triggers the sensitization of PbSe. First, a mechanism exists that iodine reduces the PL intensity significantly, as shown in FIG. 2e. Second, iodine further promotes the coalescence between PbSe crystals through fragmentation of the large microcrystals into more numerous small ones with diameters in the range of, for example, 300-500 nm, resulting in a smoother surface as shown in FIG. 1d. At the same time, the resistance increased by almost two orders of magnitude up to 2 MΩ. It is believed that the changes mentioned above, which play the key role in the p-type PbSe sensitization, are attributed to the incorporation of iodine to PbSe (iodination). However, no iodine element or iodine related phase was directly detected in our EDS and XRD measurements, indicating the concentration of iodine incorporated into PbSe is quite low.

A detectivity of 1.2×10⁹ cm·Hz^{1/2}·W⁻¹ was observed in a PbSe sample annealed in an oxygen-iodine mixture (Sample VII). Compared with the higher sensitivity of PbSe annealed in pure oxygen followed by exposure to an iodine atmosphere (Sample VI), the low sensitivity is attributed to the low crystal qualities before iodination due to insufficient recrystallization process, according to the PL results.

As an effective improver, the introduction of oxygen could enhance the sensitivity of PbSe. Based on the increased PL intensity in FIG. 2c, the enhanced sensitivity by introducing oxygen in nitrogen atmosphere, before iodination, (Sample VIII) may be attributed to the defect passivation by oxygen. The detectivity of 2.8×10¹⁹ cm·Hz^{1/2}·W⁻¹ was achieved by exposure to oxygen followed by exposure to iodine (Sample VI). It is a result of two reasons: (1) to form oxide layer in the boundary domain during oxidization; and (2) to improve the incorporation iodine into PbSe. The former is confirmed by the appearance of PbSeO₃ in XRD pattern (FIG. 3b) of annealed PbSe sample in oxygen followed by iodine (Sample V), and the latter is verified by the degraded PL intensity shown in FIG. 2f and a more coalescent structure shown in FIG. 11.

Without wishing to be bound by theory, it is believed the inventive processes which involve p-type Pb-salt high sensitivity sensitization are due to (1) incorporation of iodine into the Pb-salt film during the iodination process (iodine is a n-type dopant in Pb-salts), (2) increase in crystal quality by high-temperature recrystallization process, and (3) passivation of defects and introduction of an oxide layer in the boundary domain in the rich oxygen atmosphere.

As indicated above, different roles for oxygen and iodine in p-type Pb-salt sensitization processes have been demonstrated herein. It is evident that iodine, rather than oxygen, triggers the photo-responsibility of p-type Pb-salts. Oxygen, however, serves as an efficient sensitization improver by defect passivation, forming oxide layers at the boundary domain, and improving the iodination.

As noted above, low-cost, versatile PbS and PbSe polycrystalline thin films remain the photoconductive detectors of choice for many applications in the 1-3 μm and 3-5 μm spectral range. One can attribute the advantage of those materials in the long wavelength regime to a strong enhancement of the Auger non-radiative lifetime. While Auger processes are the primary mechanism responsible for the rapid degradation of III-V interband semiconductor device performance with increasing wavelength, it is well known that the Auger coefficient in IV-VI structures is more than an order of magnitude lower than those in type-II QWs, which are in turn significantly suppressed relative to other III-V and II-VI semiconductors with the same energy gaps. Basically, it is far more difficult to conserve both momentum and energy in an Auger process when the masses are nearly equal as in the IV-VI lead salts than when they are very unequal as in most other systems. Such low Auger recombination should result in superior device performance such as high detectivity for photovoltaic (PV) detectors and high operating temperature. However, IV-VI PV detectors with those expected advantages have not been realized. Without wishing to be bound by theory, it may be that the high Shockley-Read-Hall (SRH) recombination rate in lead-salt materials leads to short carrier lifetime and is the major cause for the inferior device performance.

The novel sensitization processes described herein has significantly increased the carrier lifetime. Application of the presently described novel sensitization processes to Pb-salt thin film materials used in PV detectors results in a significant improvement in detector performance. Such improved performance will make Pb-salt PV detectors, sensitized in the manner described herein, increasingly competitive to their counterparts in sensing and imaging applications.

Preparation of Materials and Equipment

It is necessary to thoroughly clean the calcium fluoride substrates and other apparatus to successfully produce a sensitive lead selenide films with a better uniformity. The preparation and deposition conditions described below are exemplary and are not intended to be limiting.

The substrates are rinsed vigorously ultrasonically in acetone and ethanol for 5 minutes, respectively. The substrates are then subjected to a further ultrasonic bath in distilled water for 2 minutes. The thus-cleaned substrates are then dried by high purity nitrogen gas and stored in nitrogen gas until ready to be used.

The materials of the various deposition solutions used herein include but are not limited to selenosulfate, lead acetate, sodium hydroxide, iodine, potassium iodide, selenium, sodium sulphite.

Preparation of Selenosulfate Solution

The synthesis of selenosulfate to be described herein involves the following reactions:

Se+Na₂SO₃→Na₂SeSO₃

In one embodiment, a suitable concentration of selenosulfate solution is in the range from 0.01 to 2.0M. For example, the fresh 0.01M selenosulfate solution is prepared by heating 500 mL of distilled water containing 0.5 g of selenium powder (99.999%) and 2.63 g of sodium sulphite at 90° C. for 2 h. During this process, selenium powder and sodium sulphite reacted gradely to form a selenosulfate transparent solution. The selenosulfate is stored at 4° C.

In one embodiment, a suitable concentration of lead acetate solution is in the range from 0.01 to 2.0 M. For example, the fresh 0.01M lead acetate precursor is prepared by dissolving 1.89 g lead acetate into 500 ml distilled water and stirring at 50° C. for 2 h.

In one embodiment, a suitable concentration of sodium hydroxide solution is in the range from 0.20 to 5M. For example, the 0.1M sodium hydroxide solution is obtained by dissolving 2 g sodium hydroxide into 500 ml distilled water.

In one embodiment, a suitable concentration of potassium tri-iodide solution is in the range from 0.001 to 0.1M. For example, the 0.001M potassium tri-iodide solution is prepared by dissolved 0.05 g of potassium iodide and 0.052 g iodine in 200 ml of boiling distilled water.

Preparation of Deposition Solution

Two different deposition solutions and procedures may be employed. The Solution I is prepared for a mirror-like polycrystalline lead selenide seed layer, which enhances the adherence of lead selenide to the substrate. The Solution II is prepared for thicker lead selenide films with more sensitivity. The Procedure I is designed to provide an ultra-uniform/operability regardless of the cost, while the Procedure II results in an optimum balance between uniform/operability and the cost.

Solution I

In one embodiment, a suitable concentration of lead ion in Solution I is in the range from 0.001 to 0.02M, and the suitable lead-to-selenium ion ratio of solution I is in the range from 0.5 to 2, and the lead-to-iodine ion ratio is in the range from 10 to 200. For example, 3 ml of sodium hydroxide solution, obtained as previously described, is dissolved in 20 ml of distilled water in 50 ml vessel, and then is heated at around 60-70° C. for 5 minutes. 3 ml of lead acetate solution just described is slowly dropped into the heated sodium hydroxide solution above. After vigorous stirring for 3-5 min, the mixed solution above is naturally cooled at 30-35° C. 4 ml of selenosulfate solution is then quickly mixed with mixed solution and vigorously stirred for 1 minute. 1 ml of potassium tri-iodine solution is mixed into the mixed solution described above. Finally, a transparent solution is obtained.

### Solution II

In one embodiment, a suitable concentration of lead ion in Solution II is in the range from 0.002 to 0.04M, and a suitable lead-to-selenium ion ratio of solution II is in the range from 0.5 to 2, and the lead-to-iodine ion ratio is in the range from 10 to 200. For example, 6 ml of sodium hydroxide solution, obtained as previously described, are dissolved in 15 ml of distilled water in 50 ml vessel, and is then heated at around 60-70° C. 6 ml of lead acetate solution just described is dropped into the heated sodium hydroxide solution above. After vigorous stirring for 3-5 min, the mixed solution above is naturally cooled at 30-35° C. 8 ml of selenosulfate solution is then mixed with mixed solution. Finally, 2 ml of potassium tri-iodine solution is mixed into the mixed solution described above.

Deposition Procedure I

The cleaned calcium fluoride substrate described above is firstly immersed into Solution I. The vessel is transferred into an ultrasonic cleaner containing 65-85° C. heated water. The deposition lasts for 20 minutes. The ultrasonic agitation is off in the first two minutes. Thereafter for the next 18 minutes, the ultrasonic cleaner is programmed so as to be on for 2-5 seconds for each minute. Such a deposition procedure maintains a desirable and practical deposition rate. After 20 minutes, the substrate is taken out and rinsed with distilled water. A mirror-like polycrystalline lead selenide film, as seed layer for a thicker layer of more sensitive lead selenide, shows a strong adherence to the substrate.

Subsequently, the wet mirror-like seed layer coated substrate is quickly immersed in Solution II for the second growth. The deposition of lead selenide with Solution II follows the same growth and ultrasonic programs described in Solution I, supra, to obtain the second layer of lead selenide. Then the deposition in Solution II is repeated for 8-20 times to achieve a desired thickness, e.g., about 1.0 micrometer. Finally, the lead selenide film shows a uniform and smooth surface.

Deposition Procedure II

A mirror-like lead selenide is deposited on the cleaned calcium fluoride substrate following the same deposition procedure described in deposition Procedure I. Then, the seed layer coated substrate is immersed in solution II at 65-85° C. for 20 minutes to 3 hours. The ultrasonic cleaner is programmed so as to be on for 2-5 seconds for each minute. At this point, the polycrystalline lead selenide film obtained shows a uniform surface.

Sensitization

Before heat-sensitization, the chemically deposited lead selenide films obtained from the above procedures may be stored in vacuum vessels for 12-24 hours. Then, the films may be sensitized by (1) exposure to oxygen and/or nitrogen for a duration of time in a range of about 1 min to about 60 min at a temperature in a range of from about 300° C. to about 450° C., followed by (2) exposure to an iodine vapor (which may be in a nitrogen gas or oxygen carrier gas or any other gas mixture described herein for such use), at a temperature in a range of about 300° C. to about 450° C. for about 1 min to about 60 min. In non-limiting embodiments the iodine may be supplied at a flow rate of, for example, 5-50 sccm. This sensitization results in a more stable and desirable resistivity which increases 3 orders of magnitude during the exposure period and remains constant thereafter. The sensitivity of detectors according to the methods set forth herein is found to exceed the sensitivity of lead selenide detectors prepared by standard chemical deposition. Although reference is made above to lead selenide films, it is intended that the method and apparatus referred to above and below is intended to include all lead salt films referred to elsewhere herein, including, but not limited to, PbS, PbSe, PbTe, PbSnSe, PbSnTe, PbSrSe, PbSrTe, PbEuSe, PbEuTe, PbCdSe, PbCdTe, or any lead salt containing a combination of two, three, four, or more Group IV and Group VI elements.

In certain embodiments, the presently disclosed inventive concepts include a method of sensitizing a lead salt film on a substrate (also referred to elsewhere herein as a lead salt-coated substrate). In some embodiments for example, the sensitization process in a first step uses oxygen and/or nitrogen in an annealing step. In at least one embodiment, the O₂ and/or N₂ is provided at a temperature in a range of, but not limited to, about 300° C. to about 450° C. for a duration of time in a range of, but not limited to, about 1 min to about 60 min. After the annealing step above, in at least one embodiment, I₂ in a vapor atmosphere is introduced in a second step to the lead salt-coated substrate (now annealed), at a temperature in a range of, but not limited to, about 300° C. to about 450° C. for a duration of time in a range of, but not limited to, about 1 min to about 60 min to form a sensitized lead salt-coated substrate.

Said temperature range of about 300° C. to about 450° C. is understood to include all integeric temperature values therebetween, including 301° C., 302° C., 303° C., 304° C., 305° C., 306° C., 307° C., 308° C., 309° C., 310° C., 311° C., 312° C., 313° C., 314° C., 315° C., 316° C., 317° C., 318° C., 319° C., 320° C., 321° C., 322° C., 323° C., 324° C., 325° C., 326° C., 327° C., 328° C., 329° C., 330° C., 331° C., 332° C., 333° C., 334° C., 335° C., 336° C., 337° C., 338° C., 339° C., 340° C., 341° C., 342° C., 343° C., 344° C., 345° C., 346° C., 347° C., 348° C., 349° C., 350° C., 351° C., 352° C., 353° C., 354° C., 355° C., 356° C., 357° C., 358° C., 359° C., 360° C., 361° C., 362° C., 363° C., 364° C., 365° C., 366° C., 367° C., 368° C., 369° C., 370° C., 371° C., 372° C., 373° C., 374° C., 375° C., 376° C., 377° C., 378° C., 379° C., 380° C., 381° C., 382° C., 383° C., 384° C., 385° C., 386° C., 387° C., 388° C., 389° C., 390° C., 391° C., 392° C., 393° C., 394° C., 395° C., 396° C., 397° C., 398° C., 399° C., 400° C., 401° C., 402° C., 403° C., 404° C., 405° C., 406° C., 407° C., 408° C., 409° C., 410° C., 411° C., 412° C., 413° C., 414° C., 415° C., 416° C., 417° C., 418° C., 419° C., 420° C., 421° C., 422° C., 423° C., 424° C., 425° C., 426° C., 427° C., 428° C., 429° C., 430° C., 431° C., 432° C., 433° C., 434° C., 435° C., 436° C., 437° C., 438° C., 439° C., 440° C., 441° C., 442° C., 443° C., 444° C., 445° C., 446° C., 447° C., 448° C., and 449° C., and all decimal values between said integeric values. Said temperature is also intended to include any sub-range within the range of about 300° C. to about 450° C., such as about 375° C. to about 385° C.

Said duration of time range of about 1 min to about 60 min is understood to include all integeric minute values therebetween, including, 2 min, 3 min, 4 min, 5 min, 6 min, 7 min, 8 min, 9 min, 10 min, 11 min, 12 min, 13 min, 14 min, 15 min, 16 min, 17 min, 18 min, 19 min, 20 min, 21 min, 22 min, 23 min, 24 min, 25 min, 26 min, 27 min, 28 min, 29 min, 30 min, 31 min, 32 min, 33 min, 34 min, 35 min, 36 min, 37 min, 38 min, 39 min, 40 min, 41 min, 42 min, 43 min, 44 min, 45 min, 46 min, 47 min, 48 min, 49 min, 50 min, 51 min, 52 min, 53 min, 54 min, 55 min, 56 min, 57 min, 58 min, and 59 min, and all values of seconds therebetween. Said duration of time is also intended to include any sub-range within the range of 1 min to about 60 min, such as about 10 min to about 20 min.

Oxygen used in the “pre-iodine” step can be provided in an atmosphere which is substantially pure oxygen, or can be provided in an atmosphere which is primarily oxygen (≧50%), or can be provided in a “low purity” mixture with other gases, wherein the oxygen comprises <50% of the composition. The oxygen can be provided in a mixture of gases including, for example but not necessarily limited to, one or more of nitrogen, air, and the noble gases such as helium, argon, neon, krypton, and xenon. For example, the oxygen can be supplied as a component of an air mixture, a nitrogen mixture, an argon mixture, a helium mixture, an air-argon mixture, an air-helium mixture, an air-nitrogen mixture, a nitrogen-argon mixture, an argon-helium mixture, an air-argon-helium mixture, or an air-argon-nitrogen mixture. The above examples of oxygen-gas mixtures are non-limiting examples of oxygen-gas mixtures which can be used herein.

Nitrogen used in the “pre-iodine” step can be provided in an atmosphere which is substantially pure nitrogen, or can be provided in an atmosphere which is primarily nitrogen (≧50%), or can be provided in a “low purity” mixture with other gases, wherein the nitrogen comprises <50% of the composition. The nitrogen can be provided in a mixture of gases including, for example but not necessarily limited to, one or more of oxygen, air, and the noble gases such as helium, argon, neon, krypton, and xenon. For example, the nitrogen can be supplied as a component of an air mixture, an oxygen mixture, an argon mixture, a helium mixture, an air-argon mixture, an air-helium mixture, an air-oxygen mixture, an oxygen-argon mixture, an argon-helium mixture, an air-argon-helium mixture, or an air-argon-oxygen mixture. The above examples of nitrogen-gas mixtures are non-limiting examples of nitrogen-gas mixtures which can be used herein.

As noted above, the lead salt used herein may be, but is not limited to, PbS, PbSe, PbTe, PbSnSe, PbSnTe, PbSrSe, PbSrTe, PbEuSe, PbEuTe, PbCdSe, PbCdTe, or any lead salt containing a combination of two, three, four, or more Group IV and Group VI elements. The method may further comprise coating at least a portion of the sensitized lead salt-coated substrate with a metal, for example gold, although any suitable electrically-conductive material can be used, to form a detector which has a detectivity of at least 2×10⁹ cm·Hz^{1/2}·W⁻¹ when uncooled, a detectivity of at least 4×10⁹ cm·Hz^{1/2}·W⁻¹ when uncooled, a detectivity of at least 6×10⁹ cm·Hz^{1/2}·W⁻¹ when uncooled, a detectivity of at least 8×10⁹ cm·Hz^{1/2}·W⁻¹ when uncooled, a detectivity of at least 1.0×10¹⁰ cm·Hz^{1/2}·W⁻¹ when uncooled, a detectivity of at least 1.5×10¹⁰ cm·Hz^{1/2}·W⁻¹ when uncooled, a detectivity of at least 2.0×10¹⁰ cm·Hz^{1/2}·W⁻¹ when uncooled, a detectivity of at least 2.5×10¹⁰ cm·Hz^{1/2}·W⁻¹ when uncooled, or a detectivity of at least 2.8×10¹⁰ cm·Hz^{1/2}·W⁻¹ when uncooled. In one embodiment the detectivity is in a range of at least 1.0×10¹⁰ cm·Hz^{1/2}·W⁻¹ to 2×10¹¹ cm·Hz^{1/2}·W⁻¹ when uncooled (i.e. at room temperature (298K)). The substrate of the lead salt-coated substrate may comprise, for example, glass, silica, silicon, SiO₂, calcium fluoride, sapphire, or a combination thereof, and as discussed above, may comprise a plurality of surface wells. In one embodiment, the photodetector comprises a lead salt-coated substrate produced by a method such as described above, wherein at least a portion of the sensitized lead salt-coated substrate has been coated with a metal, such as gold, although any suitable electrically-conductive material can be used, and wherein the detector has a detectivity of at least 2.8×10¹⁰ cm·Hz^{1/2}·W⁻¹ when uncooled (i.e., operated without additional cooling).

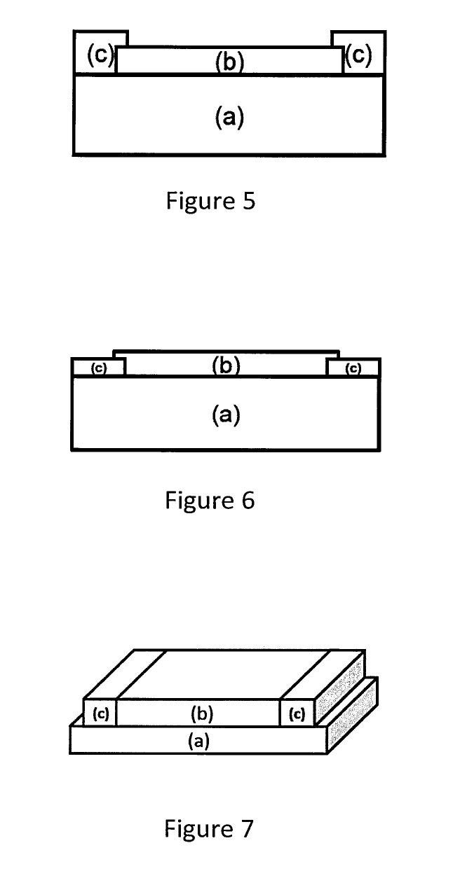

Examples of photoconductive detectors and photovoltaic detectors which can be constructed in accordance with the methods described elsewhere herein include, but are not limited to, those schematically shown in cross-sectional or perspective views in FIGS. 5-7. Represented in the figures are a substrate “a”, such as for example, but not limited to a semiconductor material such as silicon, silica, an insulative material such as glass, quartz and sapphire, a crystalline compound such as CaF₂, and SiO₂, and combinations thereof, and which may comprise a plurality of wells as discussed elsewhere herein. A Pb-salt film disposed on the substrate “a” is represented as “b”. The Pb-salt film is any such Pb-salt layer described elsewhere herein which has been sensitized using the sensitization methods of the presently disclosed inventive concepts. Electric contacts represented as “c” are disposed in alternate configurations adjacent the substrate “a” and Pb-salt film “b” as indicated in the figures. For example, the contacts “c” may partially overlap the Pb-salt film “b” (FIG. 5), or may be partially overlapped by the Pb-salt film “b” (FIG. 6), or may be adjacent and flush with the upper surface of the Pb-salt layer “b” (FIG. 7). The Pb-salt film and the electric contacts can be formed on the substrate “a” using semiconductor device fabrication techniques such as molecular beam epitaxy, chemical bath deposition, chemical vapor deposition, etching and combinations thereof. Further, the order of the techniques can be varied depending upon the desired configuration of the photoconductive detectors and photovoltaic detectors. For example, in the example of FIG. 5, the Pb-salt film “b” can be formed using chemical solution deposition, or molecular beam epitaxy on the substrate “a”. Then, predetermined portions of the Pb-salt film “b” can be removed using suitable photolithography and etching techniques, followed by application of the electric contacts “c”. In the example of FIG. 6, the electric contacts “c” may be applied to the substrate “a” prior to the formation of the Pb-salt film “b”. The photodetectors of the presently disclosed inventive concepts can be used in devices including but not limited to photovoltaic devices, lasers, solar cells, and image sensors, for example image sensors comprising one or more arrays of the photodetectors.

In certain embodiments, the presently disclosed inventive concepts are directed to a method of sensitizing a lead salt film, comprising: exposing a lead salt-coated substrate to at least one of oxygen and nitrogen for a duration of time in a range of about 1 minute to about 60 minutes at a temperature in a range of about 300° C. to about 450° C., followed by a step of exposing the lead salt-coated substrate to an iodine atmosphere for a duration of time in a range of about 1 minute to about 60 minutes at a temperature in a range of about 300° C. to about 450° C., or any temperature range or duration of time range described elsewhere herein, forming a sensitized lead salt-coated substrate. The lead salt-coated substrate may comprise a lead salt selected from the group consisting of PbS, PbSe, PbTe, PbSnSe, PbSnTe, PbSrSe, PbSrTe, PbEuSe, PbEuTe, PbCdSe, PbCdTe, and any lead salt containing a combination of two, three, four, or more Group IV and Group VI elements. In any of the above, the method may further comprise coating at least a portion of the sensitized lead salt-coated substrate with a metal to form a detector which has a detectivity within a range from 2×10⁹ cm·Hz^{1/2}·W⁻¹ to 2×10¹¹ cm·Hz^{1/2}·W⁻¹ when uncooled, a detectivity within a range from 4×10⁹ cm·Hz^{1/2}·W⁻¹ to 2×10¹¹ cm·Hz^{1/2}·W⁻¹ when uncooled, a detectivity within a range from 6×10⁹ cm·Hz^{1/2}·W⁻¹ to 2×10¹¹ cm·Hz^{1/2}·W⁻¹ when uncooled, a detectivity within a range from 8×10⁹ cm·Hz^{1/2}·W⁻¹ to 2×10¹¹ cm·Hz^{1/2}·W⁻¹ when uncooled, a detectivity within a range from 1.0×10¹⁰ cm·Hz^{1/2}·W⁻¹ to 2×10¹¹ cm·Hz^{1/2}·W⁻¹ when uncooled, or a detectivity within a range from 1.5×10¹⁰ cm·Hz^{1/2}·W⁻¹ to 2×10¹¹ cm·Hz^{1/2}·W⁻¹ when uncooled, or a detectivity within a range from 2.0×10¹⁰ cm·Hz^{1/2}·W⁻¹ to 2×10¹¹ cm·Hz^{1/2}·W⁻¹ when uncooled, or a detectivity within a range from 2.5×10¹⁰ cm·Hz^{1/2}·W⁻¹ to 2×10¹¹ cm·Hz^{1/2}·W⁻¹ when uncooled, or a detectivity within a range from 2.8×10¹⁰ cm·Hz^{1/2}·W⁻¹ to 2×10¹¹ cm·Hz^{1/2}·W⁻¹ when uncooled. In any of the above, the metal may comprise gold, although any suitable electrically-conductive material can be used. In any of the above, the lead salt-coated substrate may comprise a substrate selected from the group consisting of glass, silica, silicon, SiO₂, quartz, calcium fluoride, sapphire, and combinations thereof. In any of the above, the iodine may be provided in a mixture with at least one of oxygen, nitrogen, air, helium, argon, neon, krypton, and xenon. In any of the above the at least one of oxygen and nitrogen may be oxygen and may be provided in a mixture with at least one of nitrogen, air, helium, argon, neon, krypton, and xenon. In any of the above, the at least one of oxygen and nitrogen may be nitrogen provided in a mixture with at least one of oxygen, air, helium, argon, neon, krypton, and xenon.

In certain embodiments, the presently disclosed inventive concepts are directed to a photodetector, comprising a sensitized lead salt-coated substrate, wherein at least a portion of the sensitized lead salt-coated substrate has been coated with a metal, and wherein the photodetector has a detectivity within a range from 2×10⁹ cm·Hz^{1/2}·W⁻¹ to 2×10¹¹ cm·Hz^{1/2}·W⁻¹ when uncooled, for example as indicated elsewhere herein. The photodetector may be produced by exposing the lead salt-coated substrate to the at least one of oxygen and nitrogen for a duration of time in a range of about 1 minute to about 60 minutes at a temperature in a range of about 300° C. to about 450° C., and the lead salt-coated substrate may be exposed to the iodine atmosphere for a duration of time in a range of about 1 minute to about 60 minutes at a temperature in a range of about 300° C. to about 450° C., or any temperature range or time range described elsewhere herein. The photodetector may be a photoconductive detector or a photovoltaic detector. In any of the above, the lead salt of the lead salt-coated substrate may be selected from the group consisting of PbS, PbSe, PbTe, PbSnSe, PbSnTe, PbSrSe, PbSrTe, PbEuSe, PbEuTe, PbCdSe, PbCdTe, and any lead salt containing a combination of two, three, four, or more Group IV and Group VI elements. In any of the above the substrate of the lead salt-coated substrate may be selected from the group consisting of glass, silica, SiO₂, silicon, quartz, calcium fluoride, sapphire, and combinations thereof. In any of the above, the metal may comprise gold, although any suitable electrically-conductive material can be used. Any of the photodetectors described above may be used in a photodetector device, separately, or in an array. The photodetector device may be, but is not limited to, a photovoltaic device, a laser, a solar cell, and an image sensor.

Thus, in accordance with the present disclosure, there have been provided compositions, articles of manufacture, and apparatus, as well as methods of producing and using same, that fully satisfy the objectives and advantages set forth hereinabove. Although the presently disclosed inventive concepts have been described in conjunction with the specific drawings, experimentation, results, language and claims as set forth herein, it is evident that many alternatives, modifications, and variations will be apparent to those skilled in the art. Accordingly, it is intended to embrace all such alternatives, modifications and variations that fall within the spirit and broad scope of the presently disclosed inventive concepts.

What is claimed is:

1. A method of sensitizing a lead salt film, comprising:
exposing a lead salt-coated substrate to at least one of oxygen and nitrogen for a duration of time in a range of about 1 minute to about 60 minutes at a temperature in a range of about 300° C. to about 450° C., followed by a step of exposing the lead salt-coated substrate to an iodine atmosphere for a duration of time in a range of about 1 minute to about 60 minutes at a temperature in a range of about 300° C. to about 450° C., forming a sensitized lead salt-coated substrate.

2. The method of claim 1, wherein the lead salt-coated substrate is exposed to the at least one of oxygen and nitrogen for a duration of time in a range of about 10 minutes to about 30 minutes at a temperature in a range of about 420° C. to about 450° C., and is exposed to the iodine atmosphere for a duration of time in a range of about 3 minutes to about 30 minutes at a temperature in a range of about 350° C. to about 390° C.

3. The method of claim 1, wherein the lead salt-coated substrate is exposed to the at least one of oxygen and nitrogen for a duration of time in a range of about 15 minutes to about 25 minutes at a temperature in a range of about 435° C. to about 445° C., and is exposed to the iodine atmosphere for a duration of time in a range of about 5 minutes to about 20 minutes at a temperature in a range of about 370° C. to about 385° C.

4. The method of claim 1, wherein the lead salt-coated substrate comprises a lead salt selected from the group consisting of PbS, PbSe, PbTe, PbSnSe, PbSnTe, PbSrSe, PbSrTe, PbEuSe, PbEuTe, PbCdSe, PbCdTe, and any lead salt containing a combination of two, three, four, or more Group IV and Group VI elements.

5. The method of claim 1 further comprising coating at least a portion of the sensitized lead salt-coated substrate with a metal to form a detector which has a detectivity within a range from 2×10⁹ cm·Hz^{1/2}·W⁻¹ to 2×10¹¹ cm·Hz^{1/2}·W⁻¹ when uncooled.

6. The method of claim 5, wherein the metal comprises gold.

7. The method of claim 1 further comprising coating at least a portion of the sensitized lead salt-coated substrate with a metal to form a detector which has a detectivity within a range from 1×10¹⁰ cm·Hz^{1/2}·W⁻¹ to 2×10¹¹ cm·Hz^{1/2}·W⁻¹ when uncooled.

8. The method of claim 1 further comprising coating at least a portion of the sensitized lead salt-coated substrate with a metal to form a detector which has a detectivity within a range from 2×10¹⁰ cm·Hz^{1/2}·W⁻¹ to 2×10¹¹ cm·Hz^{1/2}·W⁻¹ when uncooled.

9. The method of claim 1 further comprising coating at least a portion of the sensitized lead salt-coated substrate with a metal to form a detector which has a detectivity within a range from 2.5×10¹⁰ cm·Hz^{1/2}·W⁻¹ to 2×10¹¹ cm·Hz^{1/2}·W⁻¹ when uncooled.

10. The method of claim 1 further comprising coating at least a portion of the sensitized lead salt-coated substrate with a metal to form a detector which has a detectivity within a range from 2.8×10¹⁰ cm·Hz^{1/2}·W⁻¹ to 2×10¹¹ cm·Hz^{1/2}·W⁻¹ when uncooled.

11. The method of claim 1, wherein the lead salt-coated substrate comprises a substrate selected from the group consisting of glass, silica, silicon, SiO₂, quartz, calcium fluoride, sapphire, and combinations thereof.

12. The method of claim 1, wherein the iodine is provided in a mixture with at least one of oxygen, nitrogen, air, helium, argon, neon, krypton, and xenon.

13. The method of claim 1, wherein the at least one of oxygen and nitrogen is oxygen provided in a mixture with at least one of nitrogen, air, helium, argon, neon, krypton, and xenon.

14. The method of claim 1, wherein the at least one of oxygen and nitrogen is nitrogen provided in a mixture with at least one of oxygen, air, helium, argon, neon, krypton, and xenon.

15. A photodetector, comprising a sensitized lead salt-coated substrate, wherein at least a portion of the sensitized lead salt-coated substrate has been coated with a metal, and wherein the photodetector has a detectivity within a range from 2×10⁹ cm·Hz^{1/2}·W⁻¹ to 2×10¹¹ cm·Hz^{1/2}·W⁻¹ when uncooled.

16. The photodetector of claim 15, produced by exposing a lead salt-coated substrate to at least one of oxygen and nitrogen for a duration of time in a range of about 1 minute to about 60 minutes at a temperature in a range of about 300° C. to about 450° C., followed by a step of exposing the lead salt-coated substrate to an iodine atmosphere for a duration of time in a range of about 1 minute to about 60 minutes at a temperature in a range of about 300° C. to about 450° C., forming the sensitized lead salt-coated substrate.

17. The photodetector of claim 15, produced by exposing a lead salt-coated substrate to at least one of oxygen and nitrogen for a duration of time in a range of about 10 minutes to about 30 minutes at a temperature in a range of about 420° C. to about 450° C., followed by a step of exposing the lead salt-coated substrate to an iodine atmosphere for a duration of time in a range of about 3 minutes to about 30 minutes at a temperature in a range of about 350° C. to about 390° C., forming the sensitized lead salt-coated substrate.

18. The photodetector of claim 15, produced by exposing a lead salt-coated substrate to at least one of oxygen and nitrogen for a duration of time in a range of about 15 minutes to about 25 minutes at a temperature in a range of about 435° C. to about 445° C., followed by the step of exposing the lead salt-coated substrate to the iodine atmosphere for a duration of time in a range of about 5 minutes to about 20 minutes at a temperature in a range of about 370° C. to about 385° C., forming the sensitized lead salt-coated substrate.

19. The photodetector of claim 15, wherein the photodetector is a photoconductive detector.

20. The photodetector of claim 15, wherein the photodetector is a photovoltaic detector.

21. The photodetector of claim 15, wherein the lead salt-coated substrate comprises a lead salt selected from the group consisting of PbS, PbSe, PbTe, PbSnSe, PbSnTe, PbSrSe, PbSrTe, PbEuSe, PbEuTe, PbCdSe, PbCdTe, and any lead salt containing a combination of two, three, four, or more Group IV and Group VI elements.

22. The photodetector of claim 15, wherein the lead salt-coated substrate comprises a substrate selected from the group consisting of glass, silica, silicon, SiO₂, quartz, calcium fluoride, sapphire, and combinations thereof.

23. The photodetector of claim 15, wherein the metal comprises gold.

24. A photodetector device, comprising an array of photodetectors, each comprising a sensitized lead salt-coated substrate, wherein at least a portion of the sensitized lead salt-coated substrate is coated with a metal, the photodetectors having detectivities within a range from 2×10⁹ cm·Hz^{1/2}·W⁻¹ to 2×10¹¹ cm·Hz^{1/2}·W⁻¹ when uncooled.

25. The photodetector device of claim 24, wherein the photodetector device is at least one of a photovoltaic device, a laser, a solar cell, and an image sensor.
